(19) United States
(12) Patent Application Publication
(10) Pub. No.: US 2005/0093581 A1
(43) Pub. Date: May 5, 2005

(54) Apparatus for generating internal voltage capable of compensating temperature variation

(76) Inventor: Dong-Keum Kang, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/745,861

(22) Filed: Dec. 24, 2003

(30) Foreign Application Priority Data
Oct. 31, 2003 (KR) 2003-76812

(51) Int. Cl. H03K 5/153

(52) U.S. Cl. 327/73

(57) ABSTRACT

An apparatus for generating an internal voltage includes a comparing unit for comparing voltage levels between a reference voltage and a comparison voltage, a current supplying unit for outputting a current to an output terminal in response to an output signal of the comparing unit, and a voltage dividing unit for outputting the comparison voltage by dividing a voltage of the output terminal in a selected dividing ratio from a plurality of dividing ratios in response to a selection signal.

### FIELD OF THE INVENTION

The present invention relates to a semiconductor device; and, more particularly, to an internal voltage generator capable of compensation temperature.

### DESCRIPTION OF RELATED ART

Generally, as a semiconductor memory chip is highly integrated, a cell size in the chip gradually becomes smaller, so that an operation voltage is decreased. An internal voltage generator for generating an internal voltage is embedded in most of semiconductor memory chips to thereby provide a voltage necessary for an operation of internal circuits in the chip for itself. There is required to uniformly provide the internal voltage with a stable level when designing the internal voltage generation circuit.

FIG. 1 is a circuit diagram illustrating a conventional internal voltage generation circuit.

As shown, the internal voltage generation circuit includes a comparator 10 for comparing levels between a reference voltage Vref and a comparison voltage Vcomp, a PMOS transistor MP1, which is coupled between a power supply voltage VDD and an output terminal Vout, whose gate receives an output of the comparator 10, and NMOS transistors MN1 and MN2 coupled between the output node N and a ground voltage VSS in series. Herein, it is preferable that the comparator 10 is configured with a differential amplifier of a current mirror type. The NMOS transistors MN1 and MN2, which are employed to divide a voltage, generate the comparison voltage Vcomp.

FIG. 2 is a circuit diagram illustrating another conventional internal voltage generation circuit which is an equalizing circuit with the internal voltage generation circuit of FIG. 1. Compared with the internal voltage generation circuit of FIG. 1, there is a difference only that resistors R1 and R2 are employed instead of the NMOS transistors MN1 and MN2. Therefore, the same references are used in FIG. 2.

Referring to FIGS. 1 and 2, an operation of the conventional internal voltage generation circuit will be described.

When the comparator 10 compares the reference voltage Vref with the comparison voltage Vcomp, if the comparison voltage Vcomp is lower than the reference voltage Vref, the comparator 10 outputs an output signal of a logic low level. Therefore, the PMOS transistor MP1 is turned on and a potential level of the output terminal Vout is increased, so that a voltage level of the comparison voltage Vcomp is increased.

On the other hand, if the comparison voltage Vcomp is higher than the reference voltage Vref, the comparator 10 outputs an output signal of a logic high level, so that the PMOS transistor MP1 is turned off and a voltage level of the comparison voltage is decreased. This comparison process is repeatedly carried out until the level of the reference voltage Vref equals to the level of the comparison voltage Vcomp.

In FIGS. 1 and 2, the comparison voltage Vcomp may be represented as following equation:
Vcomp=R2/(R1+R2)×Vout eq. 1

The comparator 10 controls the PMOS transistor MP1 in order that the comparison voltage Vcomp and the reference voltage Vref have the same level. Accordingly, Vref=Vcomp will be ultimately accomplished. When Vref=Vcomp is applied to the equation 1, an equation 2 is obtained as follows:
Vout=(R1+R2)×Vref=(1+R1/R2)×Vref eq. 2

Namely, the output voltage Vout, which is the internal voltage, depends on the reference voltage Vref and R1/R2. If the reference voltage is uniformly maintained regardless of variations of a temperature, since the R1/R2 value is constantly maintained even if the temperature is varied, a constant level of the output voltage may be maintained. As shown in FIG. 1, the MOS transistors MN1 and MN2 are employed to divide a voltage, resistance vales of resistors R1 and R2 of MOS transistor MN1 and MN2 have an identical characteristic for the temperature variation, the R1/R2 value can be constantly maintained. Also, as shown in FIG. 2, the resistors R1 and R2 are employed to divide a voltage, resistance vales of the resistors R1 and R2 are hardly varied for the temperature variation, so that the R1/R2 value can be constantly maintained.

However, if the reference voltage is varied according the temperature variation, the output voltage Vout is varied in a rate of (1+R1/R2) for the reference voltage Vref. When the voltage level of the internal voltage becomes unstable, the operation characteristic and reliability of the chip are degraded.

### SUMMARY OF THE INVENTION

It is, therefore, an object of the present invention to provide an internal voltage generation circuit capable of compensating reference voltage variation according to temperature variation.

In accordance with an aspect of the invention, there is provided an apparatus for generating an internal voltage, comprising: a comparing unit for comparing voltage levels between a reference voltage and a comparison voltage; a current supplying unit for outputting a current to an output terminal in response to an output signal of the comparing unit; and a voltage dividing unit for outputting the comparison voltage by dividing a voltage of the output terminal in a selected dividing ratio from a plurality of dividing ratios in response to a selection signal.

### BRIEF DESCRIPTION OF THE DRAWINGS

The above and other objects and features of the instant invention will become apparent from the following description of preferred embodiments taken in conjunction with the accompanying drawings, in which:

FIG. 1 is a circuit diagram illustrating a conventional internal voltage generation circuit;

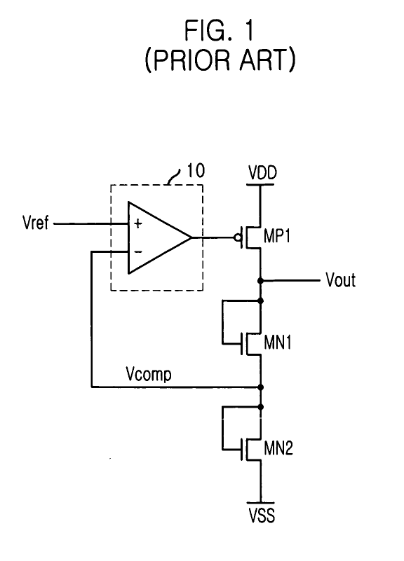

FIG. 2 is a circuit diagram illustrating another conventional internal voltage generation circuit which is an equalizing circuit with the internal voltage generation circuit of FIG. 1; and

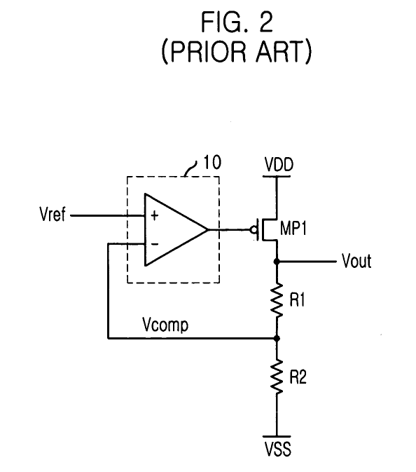

FIG. 3 is a circuit diagram illustrating an internal voltage generation circuit in accordance with the preferred embodiment of the invention.

### DETAILED DESCRIPTION OF THE INVENTION

Hereinafter, an internal voltage generation circuit according to the present invention will be described in detail referring to the accompanying drawings.

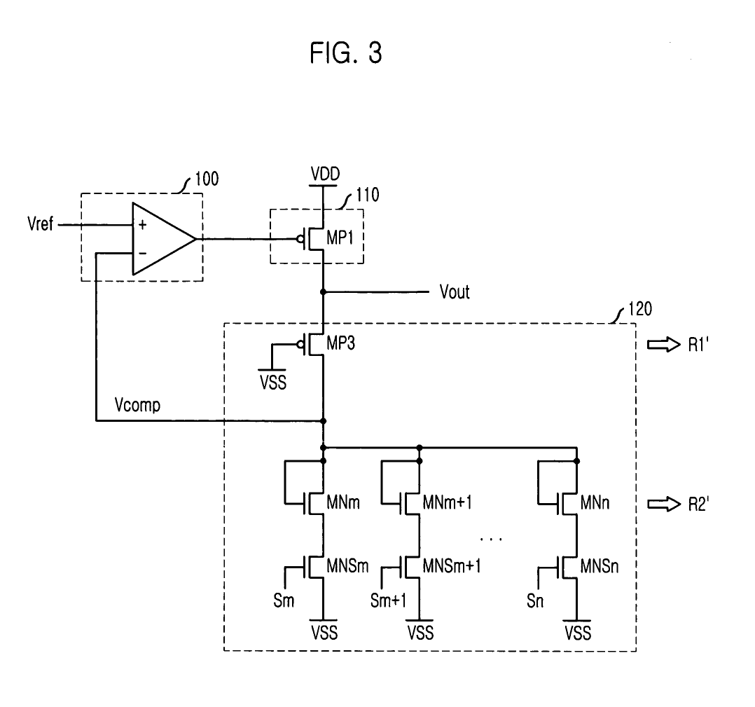

FIG. 3 is a circuit diagram illustrating an internal voltage generation circuit in accordance with the preferred embodiment of the invention.

As shown, the internal voltage generation circuit includes a comparing unit 100, a current supplying unit 110 and a voltage dividing unit 120. The comparing unit 100 compares voltage levels between a reference voltage Vref with a comparison voltage Vcomp. The current supplying unit 110 provides a current to an output node N in response to an output signal of the comparing unit 100. The voltage dividing unit 120 outputs the comparison voltage Vcomp by dividing an output voltage Vout of the output node N in a selected dividing ratio from a plurality of voltage dividing ratios in response to a plurality of selection signals Sm to Sn.

The reference voltage Vref is applied to a positive input and the comparison voltage Vcomp is applied to a negative input of the comparing unit 100, respectively. It is preferable that the comparing unit 100 is a differential amplifier of a current mirror type. The current supplying unit 110, which is coupled between the power supply voltage VDD and the output node N, is a PMOS transistor MP1 whose gate receives an output signal of the comparing unit 100.

The voltage dividing unit 120 includes a PMOS transistor MP2, which is coupled between the output node N and the comparison voltage Vcomp, whose gate is coupled to a ground voltage, a plurality of first NMOS transistors MNm to MNn, which are coupled to the comparison voltage Vcomp in parallel and each NMOS transistor has a different size, and a plurality of second NMOS transistors MNSm to MNSn, which are coupled between the first NMOS transistors MNm to MNn and a ground voltage, whose gates receive a plurality of selection signals Sm to Sn. The second NMOS transistors MNSm to MNSn are diode-coupled, respectively.

Since the gate of the PMOS transistor MP3 is coupled to the ground voltage, the PMOS transistor MP3 has a constant saturation resistance value. Of course, the resistance value may be varied according to temperature variation. Since the size of each first transistor MNm to MNn is different, each first transistor has a different turn-on resistance value. If the saturation resistance value of the PMOS transistor MP3 is defined as ‘R1’, and the turn-on resistance value of one of the first transistors MNm to MNn, which is selected by the selection signal Sm to Sn, is defined as ‘R2’, an equation 3 is obtained as follows:
Vout=(1+R1′/R2′)×Vref eq. 3

Initially, the selection signals Sm to Sn are set as a default value to select one of second NMOS transistors MNSm to MNSn corresponding to the reference voltage. If the reference voltage Vref is varied, the output voltage Vout is also varied. Namely, if the voltage level of the reference voltage Vref is varied according to the temperature variation, the voltage level of the output voltage Vout is unstable.

In accordance with the present invention, if the reference voltage Vref is varied according to the temperature variation, the default value of the selection signals Sm to Sn is changed, so that one of second NMOS transistor MNSm to MNSn is selectively turned on. Therefore, the resistance value R2 is varied. Namely, if the voltage level of the reference voltage Vref is fallen, one of first NMOS transistors MNm to MNn, which has a low turn-on resistance value, is turned on, so that the R1′/R2′ value is increased. On the other hand, if the voltage level of the reference voltage Vref is risen, one of first NMOS transistors MNm to MNn, which has a high turn-on resistance value, is turned on, so that the R1′/R2 value is decreased. Accordingly, the variation of the reference voltage Vref can be compensated.

The turn-on resistance value of the diode-coupled NMOS transistors MNm to MNn is varied according to the temperature variation. Therefore, there is initially needed to match the selection signals Sm to Sn wih a corresponding temperature range by examining the resistance value variation of the first NMOS transistors MNm to MNn according to the temperature variation. If an operator has information of the selection signals Sm to Sn, the voltage level of the internal voltage can be stabilized by setting the selection signals Sm to Sn.

The PMOS transistor MP2 can be replaced with a resistor and a plurality of diode-coupled NMOS transistors MNm to MNn can be also substituted with resistors, each having different resistance value.

In accordance with the preferred embodiment of the present invention, one of voltage dividing paths is activated by using the transistors each having different resistance value. However, if the transistors each having the same resistance value are employed, a multiplicity of voltage dividing paths are implemented and the resistance value can be adjusted by controlling the number of voltage dividing paths to be activated.

The NMOS transistor is employed as a switching device in accordance with the preferred embodiment of the present invention. Also, other switching devices are can be employed instead of NMOS transistor.

While the present invention has been described with respect to the particular embodiments, it will be apparent to those skilled in the art that various changes and modifications may be made without departing from the spirit and scope of the invention as defined in the following claims.

1. An apparatus for generating an internal voltage, comprising:
a comparing unit for comparing voltage levels between a reference voltage and a comparison voltage;
a current supplying unit for outputting a current to an output terminal in response to an output signal of the comparing unit; and
a voltage dividing unit for outputting the comparison voltage by dividing a voltage of the output terminal in a selected dividing ratio from a plurality of dividing ratios in response to a selection signal.

2. The apparatus as recited in claim 1, wherein the voltage dividing unit includes:
a first voltage falling unit coupled to the output terminal;
a plurality of second voltage falling units coupled to the first voltage falling unit, each having different resistance value; and
a plurality of switching units for selectively enabling the second voltage falling units.

3. The apparatus as recited in claim 2, wherein the first voltage falling unit includes a PMOS transistor, which is coupled between the output terminal and the comparison voltage, whose gate is coupled to a ground voltage.

4. The apparatus as recited in claim 3, wherein the second voltage falling unit includes a first NMOS transistor diode-coupled to the comparison voltage.

5. The apparatus as recited in claim 5, wherein the switching unit, which is coupled between the first NMOS transistor and the ground voltage, includes a second NMOS transistor whose gate receives the selection signal corresponding to the second voltage falling unit.

6. The apparatus as recited in claim 2, wherein the first voltage falling unit includes a first resistor coupled between the output terminal and the comparison voltage.

7. The apparatus as recited in claim 6, wherein the second voltage falling unit includes a second resistor coupled to the comparison voltage.

8. The apparatus as recited in claim 7, wherein the switching unit, which is coupled between the second resistor and the ground voltage, includes an NMOS transistor whose gate receives the selection signal corresponding to the second voltage falling unit.

9. The apparatus as recited in claim 2, wherein the comparing unit includes a differential amplifier of a current mirror type receiving the reference voltage and the comparison voltage.

10. The apparatus as recited in claim 1, wherein the current supplying unit, which is coupled between the power supply voltage and the output terminal, includes a PMOS transistor whose gate receives an output signal of the comparing unit.
